(19) United States
(12) Patent Application Publication
(10) Pub. No.: US 2016/0276246 A1
(43) Pub. Date: Sep. 22, 2016

(54) SHEET-LIKE STRUCTURE, ELECTRONIC EQUIPMENT USING THE SAME, FABRICATION METHOD OF SHEET-LIKE STRUCTURE AND ELECTRONIC EQUIPMENT

(71) Applicant: FUJITSU LIMITED, Kawasaki-shi (JP)

(72) Inventors: Yoshitaka Yamaguchi, Atsugi (JP); Masaaki Norimatsu, Atsugi (JP); Yukie Sakita, Atsugi (JP); Yoshihiro Mizuno, Kobe (JP)

(73) Assignee: FUJITSU LIMITED, Kawasaki-shi (JP)

(21) Appl. No.: 15/166,696

(22) Filed: May 27, 2016

Related U.S. Application Data
(63) Continuation of application No. PCT/JP2013/085155, filed on Dec. 27, 2013.

(51) Int. Cl. H01L 23/427; H01L 51/00; H01L 21/48; H01L 23/373; H01L 23/367

(52) U.S. Cl. CPC H01L 23/427; H01L 23/3737; H01L 23/367; H01L 21/4882; H01L 51/0048

(57) ABSTRACT

A sheet-like structure has a plurality of linear carbon chains extending in a first direction, a phase change material in which tip ends of the linear carbon chains are embedded, and a plurality of aggregates formed at root ends of the linear carbon chains and not covered with the phase change material, the aggregates being distributed in a second direction perpendicular to the first direction with less localization than the tip ends.

### CROSS REFERENCE TO RELATED APPLICATIONS

This application is a continuation application filed under 35 U.S.C. 111(a) claiming benefit of priority of PCT International Application No. PCT/JP2013/085155 filed Dec. 27, 2013 and designating the United States, which is incorporated herein by reference in its entirety.

### FIELD

The embodiments discussed herein relate to a sheet-like structure with linear carbon chains and a fabrication method thereof, as well as electronic equipment using the sheet-like structure.

### BACKGROUND

In recent years, miniaturization of semiconductor devices has been accelerated to improve the performance of electronic equipment used for central processing units (CPUs) of servers or personal computers. The rate of heat generation per unit area is increasing more and more and heat dissipation from electronic equipment is a serious problem. In general, a heat spreader made of a high thermal conductivity material (such as copper) is provided onto a semiconductor device with a thermal interface material (TIM) inserted between the heat spreader and the semiconductor device.

It is desired for thermal interface materials to have a property of good physical contact with the uneven and rough surfaces of the heat source and the heat spreader over a wide area, in addition to its own high thermal conductivity.

Under these circumstances, a thermally conductive sheet using linear carbon chains such as carbon nanotubes or carbon nanowires has been attracting attention for applications to TIMs. Carbon nanotubes have high flexibility and sufficient heat resistance, as well as high thermal conductivity (1500 W/m*K). These characteristics give carbon nanotubes potential in applications to heat dissipation materials.

As an application of CNTs, a thermal conductive sheet using bundles of CNTs grown oriented and embedded in a resin is proposed. See, for example, Japanese Patent Application Laid-open Publication No. 2009-164552 (Patent Document 1). A structure for deforming the end portions of CNTs for the purpose of improving the connectivity at the interface of a heat dissipation sheet using CNTs is also known. See, for example, Japanese Patent Application Laid-open Publication No. 2011-204749 (Patent Document 2). Another known technique is to perform surface treatment and coating on CNTs to provide mechanical strength to the CNTs. See, for example, Japanese Patent Application Laid-open Publication No. 2012-199335 (Patent Document 3).

The conventional thermal conductive sheets described above do not sufficiently make use of high thermal conductivity of CNTs. With the structure of bending the end portions of vertically oriented CNTs in a direction parallel to the sheet surface in Patent Document 2, the phase change material (i.e., the resin) remains on the sheet surface when the load applied during reflow is insufficient. On the other hand, with an excess amount of load, the CNT heat transfer sheet becomes thin and it cannot absorb warp or curved deformation of a heat source device. In either case, satisfactory heat transfer ability cannot be achieved.

In Patent Document 3, vertically oriented CNTs are coated with a coating material and adjacent CNTs are bound by the coating material. The apparent aspect ratio becomes smaller and the buckling stress is enhanced. However, freedom of deformation is limited in CNTs due to the binding of CNTs using coating treatment, and contact between the CNTs and the heat source device and between the CNTs and a heat sink (or a heat spreader) is disturbed. As the number of CNTs in contact with both the heat source device and the heat sink (or heat spreader) is restricted, the thermal conductivity is degraded and sufficient heat dissipation or heat transfer cannot be achieved.

Still another known technique is to immerse portions of CNTs into a resin containing an organic solvent and volatilize the organic solvent to make the CNT growing ends denser than the CNT root end. See, for example, PCT International Publication WO 2007/111107 (Patent Document 4).

### SUMMARY

According to an aspect of the embodiments, a sheet-like structure includes
a plurality of linear carbon chains extending in a first direction,
a phase change material in which tip ends of the linear carbon chains are embedded, and
a plurality of aggregates formed at root ends of the linear carbon chains and uncovered with the phase change material, the aggregates being distributed in a second direction perpendicular to the first direction with less localization than the tip ends.

According to another aspect of the embodiments, a sheet-like structure fabrication method includes
forming a plurality of linear carbon chains on a substrate, the linear carbon chains being oriented in a first direction,
embedding tip ends of the linear carbon chains in a phase change material,
removing the linear carbon chains from the substrate while keeping root ends of the linear carbon chains uncovered with the phase change material, and
aggregating the root ends of the removed linear carbon chains.

The object and advantages of the invention will be realized and attained by means of the elements and combinations particularly pointed out in the claims. It is to be understood that both the foregoing general description and the following detailed description are exemplary and explanatory and are not restrictive to the invention as claimed.

### BRIEF DESCRIPTION OF DRAWINGS

FIG. 1A is a schematic diagram of a sheet-like structure according to an embodiment;

FIG. 1B represents a SEM image of self-assembled aggregates of CNTs at their root ends;

FIG. 1C represents a SEM image of the self-assembled aggregates of CNTs at their root ends;

FIG. 2A illustrates a fabrication process of the sheet-like structure of FIG. 1A;

FIG. 2B illustrates a fabrication process of the sheet-like structure of FIG. 1A;

FIG. 2C illustrates a fabrication process of the sheet-like structure of FIG. 1A;

FIG. 2D illustrates a fabrication process of the sheet-like structure represented by FIG. 1A to FIG. 1C;

FIG. 3 is a schematic diagram of electronic equipment using the sheet-like structure represented by FIG. 1A to FIG. 1C;

FIG. 4A represents the bonded interface between a heat source and the tip end of the sheet-like structure according to an embodiment;

FIG. 4B represents the bonded interface between a heat source and the tip end of a conventional structure for comparison;

FIG. 5 illustrates advantageous effects of the sheet-like structure according to an embodiment;

FIG. 6A is a schematic diagram of a sheet-like structure according to an embodiment; and

FIG. 6B illustrates advantageous effects of the sheet-like structure according to the embodiment.

### DESCRIPTION OF EMBODIMENTS

Observing carbon nanotubes (CNTs) grown on a substrate, the length of carbon nanotubes varies at their growing ends (hereinafter called “tip ends”) and the carbon nanotubes are curly-entangled with each other at the tip ends. The inventors found a technical problem in that when compressively deforming a CNT heat transfer sheet by applying a load in the orienting direction of carbon nanotubes, anisotropic deformation occurs in the CNTs. The inventors also found that, under the load in the orienting direction, deformation occurs at the root ends of the carbon nanotubes dominantly, and the tip ends of the carbon nanotubes do not deform easily.

In order to achieve a high heat transfer rate in a thermal conductive sheet using carbon nanotubes, the following factors are useful. Namely, providing mechanical strength to the carbon nanotubes in the direction of their vertical orientation while maintaining freedom of deformation at each of the carbon nanotube; and increasing the area contacting a heat source by dominantly deforming the tip ends of the carbon nanotubes with varied length, compared with root ends.

To achieve a sheet-like structure with mechanical strength and improved thermal contacting property, the tip ends of the carbon nanotubes with variation in length are consolidated by a phase change material, while the root ends with a uniform length are aggregated outside the phase change material.

By inserting this sheet-like structure between a heat source and a heat sink (or heat spreader) such that the tip ends of the carbon nanotubes come into contact with the heat source, electronic equipment with high heat transfer rate is realized. When bonding the sheet-like structure, the phase change material melts and the tip ends of the carbon nanotubes come into close contact with the heat source along its uneven and rough surface. On the other hand, the aggregated root ends of the carbon nanotubes have a buckling stress greater than the tip ends and they can support the heat sink or heat spreader securely. The structure and a fabrication method of such a sheet-like structure using carbon nanotubes are described in more detail below.

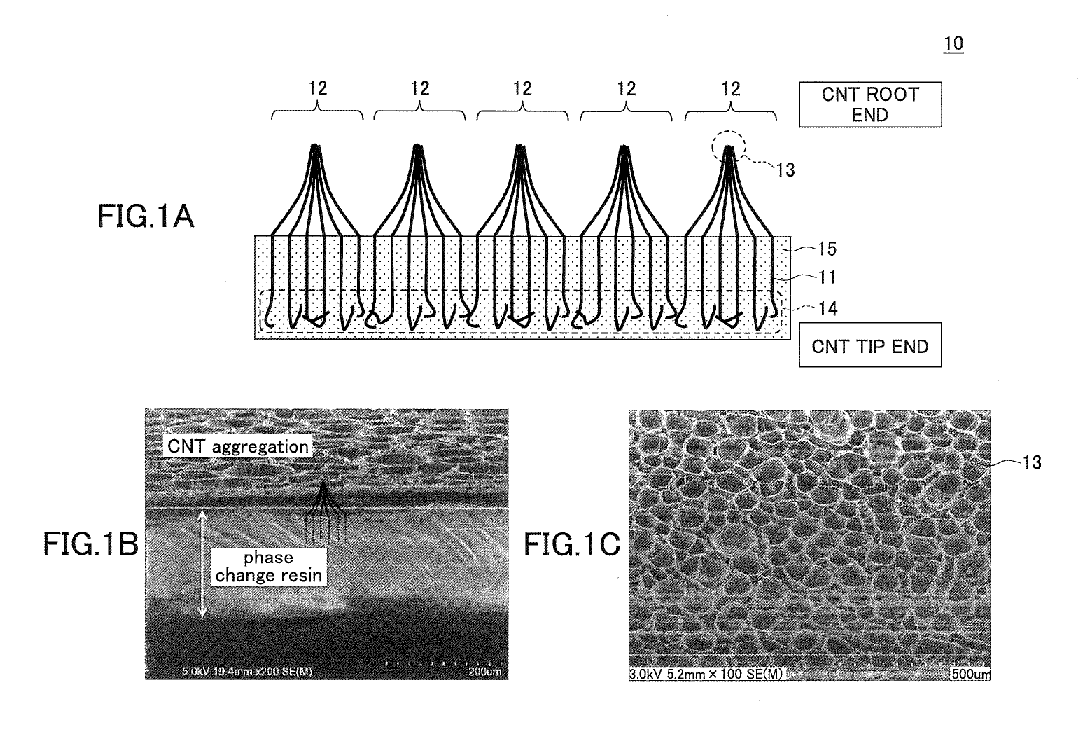

FIG. 1A is a schematic diagram of a sheet-like structure 10 according to an embodiment, and FIG. 1B and FIG. 1C are scanning electron microscope (SEM) images of CNT aggregates 13 of the sheet-like structure 10. The sheet-like structure 10 has a plurality of linear carbon chains 11, a phase change material 15 filling in a gap between tip ends 14 of the linear carbon chains 11, and aggregates 13 located at root ends of the linear carbon chains 11 and not covered with the phase change material 15.

The linear carbon chains 11 are, for example, vertically oriented single-walled or multi-walled carbon nanotubes. In the embodiment, the linear carbon chains 11 may be called “carbon nanotubes 11.” In place of coaxial nanotubes, carbon nanowires with a carbon chain inside the innermost tube or carbon nanorods may be used.

The growing ends, that is, the tip ends 14 of the carbon nanotubes 11 are embedded in a phase change material 15. The phase change material 15 undergoes reversible phase transition between liquid and solid states upon external stimulus such as heat or light. The phase change material 15 may be, example, a thermoplastic resin such as an acrylic resin, a polyethylene resin, a polystyrene resin, or polycarbonate, a B-stage resin, or a metal material.

The carbon nanotubes 11 form aggregates 13 at their root ends, each aggregate being formed of a bundle 12 of carbon nanotubes 11 of a certain area. The aggregates 13 may be, for example, a honeycomb-shaped network as represented in FIG. 1B and FIG. 1C. The root ends of carbon nanotubes 11 can be distinguishable from the tip ends 14 because of their uniform length (separated from a growth substrate) and the open edge structures with carbon dangling bonds. Although in FIG. 1B and FIG. 1C the aggregates 13 form a regularly arranged honeycomb network, the aggregates 13 may be arranged at random over the entire surface of the sheet-like structure 10 or arranged on lines or stripes.

The buckling stress of the aggregates 13 is greater than the of the CNT tip ends 14, as will be explained in more detail below. Accordingly, upon application of a load onto the sheet-like structure 10 with melting phase change material 15, the tip ends 14 of the carbon nanotubes 11 deform dominantly, following the uneven and/or rough surface shape of a heat source (not illustrated in FIG. 1A to FIG. 1C). The buckling stress of the aggregates 13 is expressed as a function of aspect ratio of the CNT bundle 12 projecting from the phase change material 14. Accordingly, by controlling the amount of percolation of the phage change material 15, the buckling stress of the aggregates 13 can be adjusted.

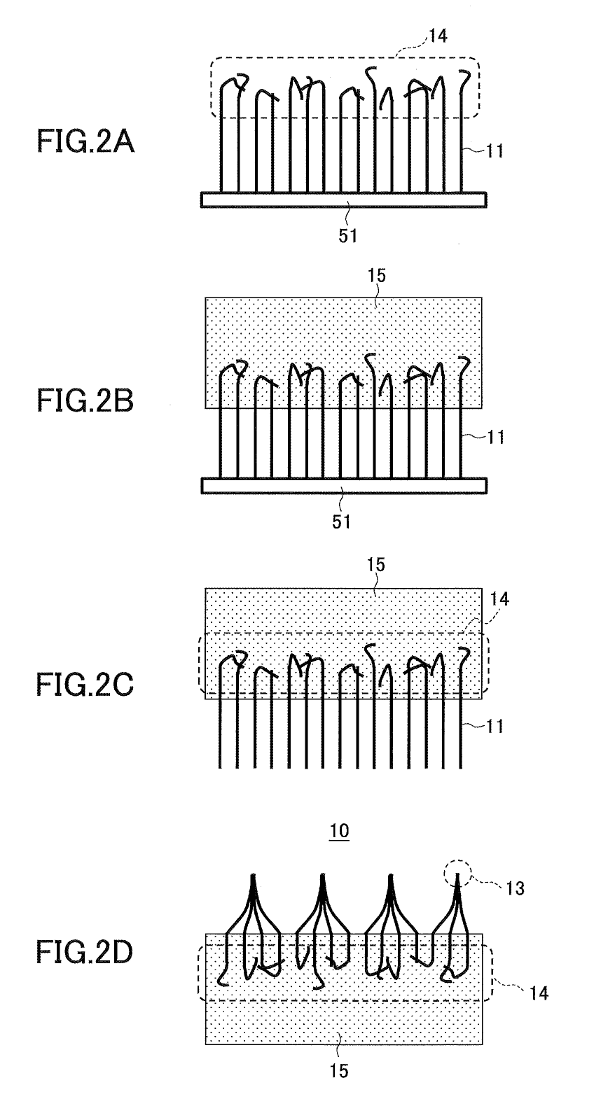

FIG. 2A to FIG. 2D illustrate a fabrication process of a sheet-like structure 10.

First, in FIG. 2A, carbon nanotubes 11 are grown on a substrate 51. As for growth, the carbon nanotubes 11 vary in length at the tip ends 14. It is desired that the surface density of the carbon nanotubes 11 is equal to or greater than 1×10¹⁰/cm² from the viewpoint of heat dissipation and electrical conductivity. The length of carbon nanotubes 11 is determined depending on use of heat spreading or TIM sheet and it may be set to 100 μm to 300 μm, but is not limited to this example.

Any suitable substrate may be used as the substrate 51, including a semiconductor substrate such as silicon substrate, an alumina or sapphire substrate, a magnesium oxide (MgO) substrate, a glass substrate, and a substrate on which a thin film is deposited. For example, a silicon substrate with a silicon oxide film of about 300 nm thick thereon may be used.

The substrate 51 is removed after the carbon nanotubes 11 have grown. It is preferable for the substrate 51 to be stable in quality and property at a growth temperature of the carbon nanotubes 11. It is also desired for the substrate 51 that at least the CNT growing surface is made of a material easily separated from the carbon nanotubes or selectively etched leaving the carbon nanotubes 11 as they are.

To form carbon nanotubes 11, a catalyst layer (not illustrated) such as an iron (Fe) layer with a thickness of 2.5 nm is formed on the substrate 51 by sputtering. The pattern layout of the catalyst metal layer is determined depending on use of the carbon nanotubes 11. For the catalyst metal, cobalt (Co), nickel (Ni), gold (Au), silver (Ag), platinum (Pt) or an alloy containing at least one of these metals may be used in place of or together with Fe.

Carbon nanotubes 11 are grown on the catalyst metal layer over the substrate 51 by hot filament chemical vapor deposition (CVD), thermal CVD, remote plasma-enhanced CVD, or other suitable methods. The source gas is, for example, a mixture of acetylene and argon (at the ratio of partial pressures one to nine). As the carbon source, a hydrocarbon such as methane or ethylene, as well as alcohol such as ethanol or methanol, may be used other than acetylene. By controlling the total gas pressure in the film deposition chamber, hot filament temperature and growth time, single-walled or multi-walled carbon nanotubes with a desired length can be grown.

In the example of FIG. 2A, carbon nanotubes 11 with length of 100 μm and diameter of 15 nm are grown at area occupancy of 3%. Under these conditions, variation in length at the tip ends 14 of the carbon nanotubes 11 is about 5 μm.

Then in FIG. 2B, the gap between carbon nanotubes 11 is filled with a phase change material 15 at the tip ends 14. The phase change material 15 is, for example, a thermoplastic resin (e.g., OM 681 manufactured by Henkel Japan Ltd.). The viscosity of a thermoplastic resin changes depending on temperature and the percolation depth in the carbon nanotubes 11 can be adjusted. A thermoplastic resin shaped into a film may be used. Using a thermoplastic resin film, the resin percolates uniformly into the carbon nanotubes 11 over a wide area. In this embodiment, a resin film is heated and melts at 165° C. such that the resin percolates through the carbon nanotubes 11 at the tip ends 14 to 20 μm depth. After the resin percolation, temperature is returned to room temperature. The thermoplastic resin is cooled and solidified, and it becomes easy to handle. The thermoplastic resin used in FIG. 2B has a viscosity equal to or less than 250,000 Pa*s and it can be treated as a solid. Other types of thermoplastic resin, B-stage resin, or metal material may be used as the phase change material 15.

Then in FIG. 2C, the array of carbon nanotubes 11 is removed from the substrate 51. As a result, a structure of carbon nanotubes 11 with the tip ends 14 embedded in the thermoplastic resin and the root ends with a uniform length projecting from the phase change material 15 is obtained.

Then in FIG. 2D, the structure obtained in FIG. 2C is immersed in water and dried. Through this process, the root ends of the carbon nanotubes 11 aggregate and form a self-assembled honeycomb network, keeping the vertical orientation of the carbon nanotubes projecting from the phase change material 15. Thus, a sheet-like structure 10 with aggregates 13 at the root ends is fabricated.

Aggregates in this context represent gatherings of carbon nanotubes, which gatherings are distributed in a plane of the root ends with less localization or more regularity compared with the tip ends 14 of the carbon nanotubes 11 held in the phase change material 15.

The solvent for aggregating the carbon nanotubes 11 is not limited as long as it does not cause denaturation or dissolution of the phase change material 14 applied to the tip ends 14 of the carbon nanotubes 11. Other than water described above, alcohol, ketone-based solution, aromatic solvent, or a mixture thereof may be used. Instead of being immersed in the solvent, the sheet-like structure 10 of the carbon nanotubes 11 may be exposed to solvent vapor. Through dew condensation and drying, carbon nanotube aggregate structures can be acquired. The carbon nanotubes 11 are pushed aside by water drops generated by surface tension of water molecules or droplets generated by dew condensation of solvent vapor and they form aggregates 13.

The aggregates 13 are preferably honeycomb-shaped, but they are not limited to this example. Because the root ends of the carbon nanotubes 11 have little variation in length, aggregates 13 with a uniform height can be formed through self-assembled aggregation. The buckling stress of the aggregates 13 is greater than that of the tip ends 14.

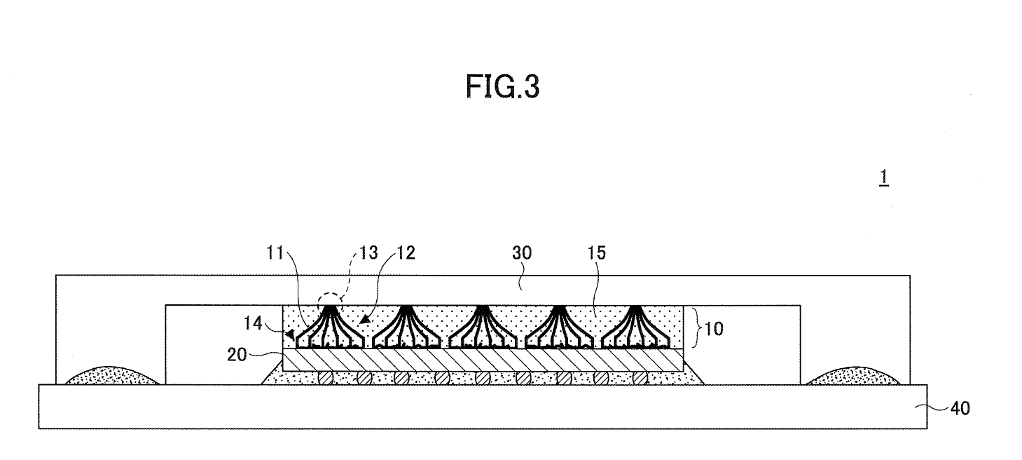

FIG. 3 is a schematic diagram of electronic equipment in which the sheet-like structure 10 fabricated by the process of FIG. 2A to FIG. 2D is incorporated. The sheet-like structure 10 is provided between a heat source 20 such as a semiconductor device and a heat spreader 30. The heat spreader is fixed to a circuit board 40 on which the heat source 20 is mounted. To bond the sheet-like structure 10 to the heat source 20 and the heat spreader 30, a load is applied while heating at a melting temperature of the phase change material 15. The phase change material 15 covering the tip ends 14 of the carbon nanotubes 11 melts and moves away from the interface between the tip ends 14 of the carbon nanotubes 11 and the heat source 20. Prior to the assembly of the electronic equipment 1, the sheet-like structure 10 may be pre-attached to the heat spreader 30.

Because the buckling stress of the aggregates 13 of the CNT bundles 12 is greater than that of the tip ends 14, the tip ends 14 touching the heat source 20 deform dominantly while following the surface shape of the heat source 20. Consequently, the sheet-like structure 10 can securely cover the hot spots on the heat source 20. On the opposite side, the aggregates 13 with a uniform height come into contact with the heat spreader 30 over the entire interface area.

For example, the sheet-like structure 10 is assembled into the electronic equipment 1 under the conditions of 200° C., 0.2 MPa and 10 minutes. The viscosity of the phase change material (e.g., thermoplastic resin) 15 used in the embodiment decreases to 10 Pa*s at 200° C. with increased fluidity. The melting phase change material 15 percolates through the carbon nanotubes 11 forming aggregates 13, and excess resin is pushed aside toward the periphery. Since the melting phase change material (thermoplastic resin) 15 with reduced viscosity has a low resistance against the load, the carbon nanotubes 11 receive almost all the load applied.

In estimating a buckling stress for the sheet-like structure 10 with aggregates 13, the estimation value is 0.04 MPa at the tip ends 14 of the carbon nanotubes 11, and 0.26 MPa at the root ends (i.e., at the aggregates 13). When carrying out the assembling at pressure of 0.2 MPa, the tip ends 14 of the carbon nanotubes 11 plastically deform along the bonded interface absorbing the variation in length of the carbon nanotubes 11. At this moment, the root ends of the carbon nanotubes 11 maintain elastic deformability and deform following the surface shape of the bonded interface. After the assembling, the electronic equipment is cooled still under the load, the phase change material (thermoplastic resin) 15 solidifies again.

Through this re-solidification, adhesiveness is exhibited at the interface between the sheet-like structure 10 and the heat source 20 and the interface between the sheet-like structure 10 and the heat spreader 30. The sheet-like structure 10 is fixed while maintaining the deformation of the carbon nanotubes 11 subjected during the assembling.

In the above-described embodiment, the phase change material (thermoplastic resin) 15 originally filling in between the tip ends 14 of the carbon nanotubes 11 is used to fill the gap between the carbon nanotubes 11 of the aggregates 13. However, a second phase change material may be used to fill the gap between carbon nanotubes of the aggregates 13 projecting from the first phase change material 15 for the assembling.

In either case, freedom of deformation of carbon nanotubes 11 is guaranteed at the tip ends 14, and the tip ends 14 can deform sufficiently to make tight contact with the heat source 20 regardless of the variation in length. At the root ends, the aggregates 13 have a buckling stress higher than the tip ends, which confers mechanical strength and satisfactory load tolerance to the sheet-like structure 10 as a whole.

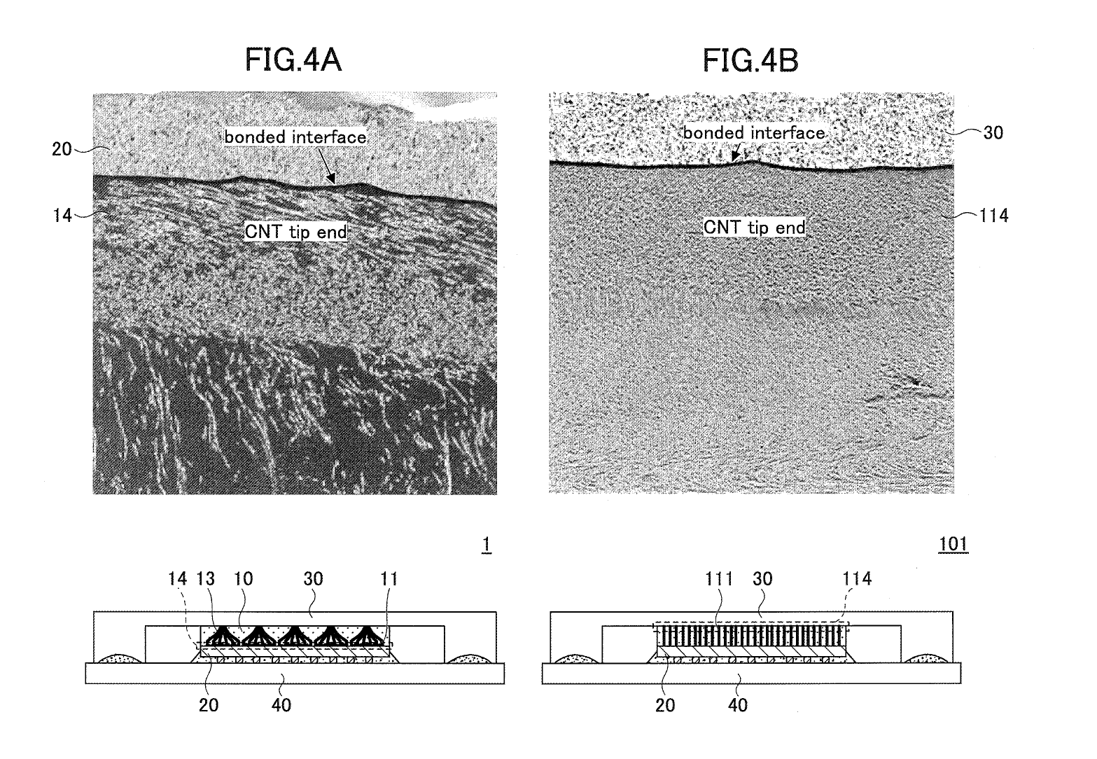

FIG. 4A and FIG. 4B illustrate advantageous effects of the sheet-like structure 10 of the embodiment over the conventional structure. FIG. 4A represents a SEM image of the bonded interface between the heat source 20 and the tip ends 14 of the carbon nanotubes 11 of the embodiment, together with a schematic diagram of electronic equipment 1. For comparison, FIG. 4B represents a SEM image of the bonded interface between a heat spreader 30 and a conventional CNT sheet, together with a schematic diagram of electronic equipment 101. The conventional CNT sheet has carbon nanotubes 111 whose tip ends are coated with a 2.5 nm thick Al₂O₃ film by an ALD method,

In FIG. 4B, the root ends of the carbon nanotubes 111 come into contact with the heat source 20, and the tip ends 113 are in contact with the heat spreader 30. With this configuration, adjacent carbon nanotubes 111 are bound together by the coating material and the deformation of carbon nanotubes 111 is prevented at or near the bonded interface.

In contrast, in FIG. 4A, the tip ends 14 of carbon nanotubes 11 plastically deform and well follow the surface shape of the heat source 20. Besides, the sheet-like structure 10 is furnished with mechanical strength as a whole without film coating on the carbon nanotubes because of the aggregates 13 located at the root ends.

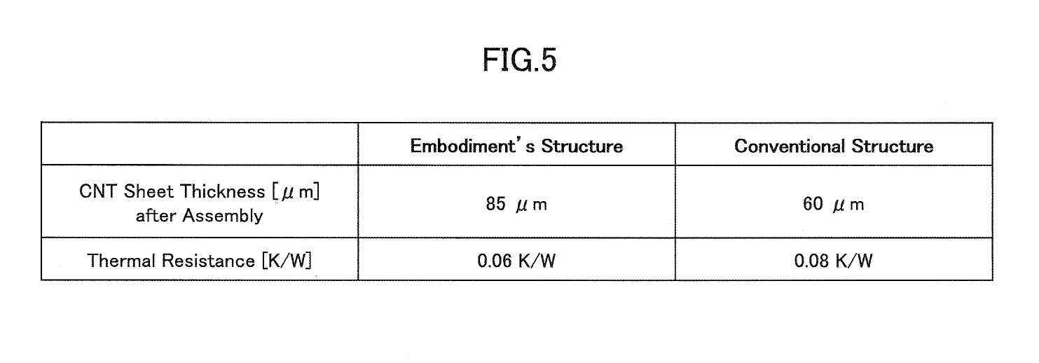

FIG. 5 represents a comparison result between the sheet-like structure 10 of the embodiment in FIG. 4A and the conventional CNT sheet in FIG. 4B. Post-assembling thickness of the CNT sheet and thermal resistance are compared. In both structures of FIG. 4A and FIG. 4B, the initial length L of carbon nanotubes 11 and 111 is 100 μm, and the assembling load is 0.3 MPa.

In the structure of FIG. 4A of the embodiment, length L1 of the tip ends 14 of the carbon nanotubes 11 to be embedded in the phase change material 15 is set to 20 μm before the assembling. Length L2 of the root ends not covered with the phase change material 15 is set to 80 μm before aggregation. In the conventional structure of FIG. 4B, carbon nanotubes 111 are coated with 2.5 nm thick Al₂O₃ film by an ALD method to add mechanical strength to the CNT sheet.

As indicated in FIG. 5, the thickness of the sheet-like structure (or CNT sheet) 10 of the embodiment assembled under 0.3 MPa load is 85 μm. The thickness of the conventional CNT sheet assembled under the same load is 60 μm in spite of the ALD coating.

Concerning the thermal resistance, the conventional structure has 0.08 K/W thermal resistance. In contrast, the thermal resistance of the sheet-like structure of the embodiment is reduced to 0.05 K/W. It is understood that the heat transfer rate is improved in the structure of the embodiment.

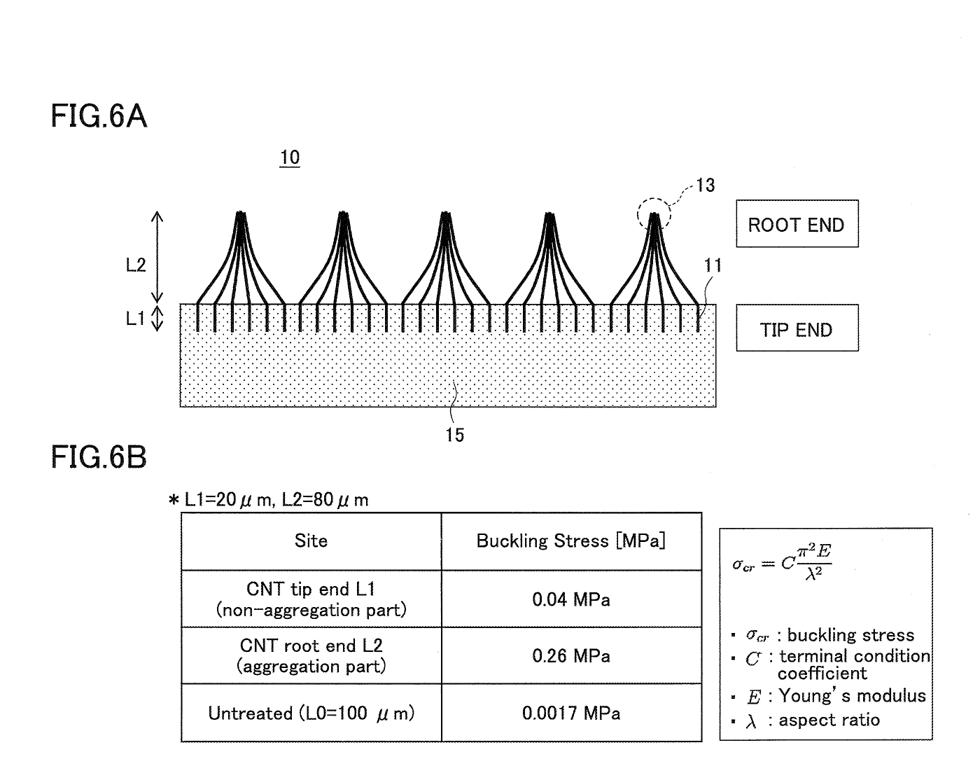

FIG. 6A and FIG. 6B are diagrams to explain the buckling stress of the tip ends of the sheet-like structure 10 and that of aggregates 13 at the root ends according to the embodiment. Carbon nanotubes 11 are grown to length 100 μm and diameter 15 nm. Length L1 of the tip ends 14 of the carbon nanotubes 11 to be embedded in the phase change material 15 is set to 20 μm. Length L2 of the root ends uncovered with the phase change material 15 is set to 80 μm.

Buckling stress σ_{cr} is expressed by Euler's formula (1).

σ_{cr}=Cπ²E/λ² (1)

where C denotes terminal condition coefficient, E denotes Young's modulus, and λ denotes aspect ratio. With the sheet-like structure 10 fabricated in the embodiment, the Young's modulus E is 1000 GPa, and the terminal condition coefficient C is 0.25 (C=0.25).

The aspect ratio λ1 at the tip ends is 20 μm to 15 nm. Assuming that the area occupancy of the carbon nanotubes 111 is 3%, the buckling stress of the sheet-like structure 10 at the tip ends becomes 0.04 MPa from formula (1).

When an aggregate 13 is formed by 4,444 carbon nanotubes, the diameter or the width of the aggregate 13 is 1 μm at the end part. The aspect ratio λ2 of the aggregate 13 is estimated as 80 μm to 1 μm. From formula (1), the buckling stress of one aggregate 13 is 385 MPa. Assuming that the area occupancy of the aggregates 13 is 6.75×10⁻⁴%, the buckling stress of the sheet-like structure 10 at the root ends becomes 0.26 MPa.

For comparison, the buckling stress of untreated carbon nanotubes is estimated. The aspect ratio of the untreated carbon nanotubes is 100 μm to 15 nm, the area occupancy is 3%, the Young's modulus of the carbon nanotube is 1000 GPa, and the terminal condition coefficient C is 0.25. Under these conditions, the buckling stress of the untreated carbon nanotube becomes 0.0017 MPa.

From the foregoing examples, it is understood that the sheet-like structure 10 of the embodiment has a greater buckling stress at the root ends than at the tip ends. The tip ends 14 of the carbon nanotubes 11 are brought into contact with the heat source 20, and the aggregates 13 formed at the root ends are connected to the heat spreader 30. By selecting an appropriate level of bonding load, the contact area at the interface between the sheet-like structure 10 and the heat source 20 can be maximized, while maintaining the thickness of the sheet-like structure 10.

All examples and conditional language provided herein are intended for the pedagogical purpose of aiding the reader in understanding the invention and the concepts contributed by the inventor to further the art, and are not to be construed as limitations to such specifically recited examples and conditions, nor does the organization of such examples in the specification relate to a showing of superiority or inferiority of the invention. Although one or more embodiments of the present invention have been described in detail, it should be understood that the various changes, substitutions, and alterations could be made hereto without departing from the spirit and scope of the invention.

What is claimed is:

1. A sheet-like structure comprising:
a plurality of linear carbon chains extending in a first direction,
a phase change material in which tip ends of the linear carbon chains are embedded, and
a plurality of aggregates formed at root ends of the linear carbon chains and not covered with the phase change material, the aggregates being distributed in a second direction perpendicular to the first direction with less localization than the tip ends.

2. The sheet-like structure as claimed in claim 1,
wherein a buckling stress of the sheet-like structure is greater at the root ends than at the tip ends.

3. The sheet-like structure as claimed in claim 1,
wherein the aggregates have a uniform height.

4. The sheet-like structure as claimed in claim 1,
wherein the tip ends of the linear carbon chains vary in length.

5. The sheet-like structure as claimed in claim 1,
wherein the phase change material includes a thermoplastic resin.

6. Electronic equipment comprising:
a heat source;
a heat spreader; and
a sheet-like structure provided between the heat source and the heat spreader,
wherein the sheet-like structure has
a plurality of linear carbon chains extending in a first direction,
a phase change material in which tip ends of the linear carbon chains are embedded, and
a plurality of aggregates formed at root ends of the linear carbon chains and not covered with the phase change material, the aggregates being distributed in a second direction perpendicular to the first direction with less localization than the tip ends.

7. The electronic equipment as claimed in claim 6;
wherein the sheet-like structure is positioned such that the tip ends of the linear carbon chains are in contact with the heat source.

8. The electronic equipment as claimed in claim 6,
wherein the tip ends of the linear carbon chains plastically deform with a variation in length.

9. The electronic equipment as claimed in claim 6;
wherein the sheet-like structure is positioned such that the aggregates are in contact with the heat spreader.

10. The electronic equipment as claimed in claim 6;
wherein the phase change material is a thermoplastic resin to bond the sheet-like structure to the heat source and the heat spreader.

11. A fabrication method of a sheet-like structure, comprising:
forming a plurality of linear carbon chains on a substrate, the linear carbon chains being oriented in a first direction;
embedding tip ends of the linear carbon chains in a phase change material;
removing the linear carbon chains from the substrate while keeping root ends of the linear carbon chains uncovered with the phase change material; and
aggregating the root ends of the removed linear carbon chains.

12. The fabrication. method as claimed in claim 11,
wherein a length of the uncovered root ends of the linear carbon chains is determined according to a target buckling stress at the root ends.

13. The fabrication method as claimed in claim 11, wherein the aggregates are created by immersing the root ends of the linear carbon chains in water and then drying.

14. A fabrication method of electronic equipment, comprising:
forming a plurality of linear carbon chains on a substrate, the linear carbon chains being oriented in a first direction;
embedding tip ends of the linear carbon chains in a phase change material;
removing the linear carbon chains from the substrate while keeping root ends of the linear carbon chains uncovered with the phase change material;
aggregating the root ends of the removed linear carbon chains to acquire a sheet-like structure; and
providing the sheet-like structure between a heat source and a heat spreader.

15. The fabrication method as claimed in claim 14,
wherein sheet-like structure is positioned such that the tip ends of the linear carbon chains are connected to the heat source and the root ends of the linear carbon chains are connected to the heat spreader.

16. The fabrication method as claimed in claim 15, further comprising:
applying heat and pressure to an assembled structure in which the sheet-like structure is positioned between the heat source and the heat spreader, whereby the tip ends of the linear carbon chains plastically deform along a surface of the heat source.
